(19) United States
(12) Patent Application Publication
(10) Pub. No.: US 2010/0176788 A1
(43) Pub. Date: Jul. 15, 2010

(54) CURRENT DETECTING APPARATUS

(75) Inventor: CHIA-HUNG SUN, Tucheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXNUM TECHNOLOGY CO., LTD., Tucheng City (TW)

(21) Appl. No.: 12/400,792

(22) Filed: Mar. 9, 2009

(30) Foreign Application Priority Data
Jan. 13, 2009 (CN) 200910300171.5

(51) Int. Cl. G01R 19/00

(52) U.S. Cl. 324/76.11

(57) ABSTRACT

A current detecting apparatus for detecting a current provided by a driver for a motor includes a resistor, a signal isolation module, and a processor. A first end of the resistor is connected to the driver, and a second end of the resistor is connected to the motor. A current provided by the driver passes through the resistor to drive the motor. The signal isolation module is connected between the first end and the second end of the resistor, to receive a voltage signal produced by the current passing through the resistor and isolate the voltage signal to output an isolated signal. The processor is connected to the signal isolation module, to receive the isolated signal and process the isolated signal to detect the current provided by the driver for the motor.

### BACKGROUND

1. Technical Field

The present disclosure relates to detecting apparatuses, and particularly to a current detecting apparatus.

2. Description of the Related Art

Generally, a current provided by a driver for a motor is detected by a current sensor. Typically, the kind of current sensor used in such a driver will only detect the current in increments, such as 5 A, 10 A, 20 A, 30 A, or 50 A, and so on. Therefore, detection of the current may not be very precise, for example, when the current of the motor is about 24 A, the sensor may detect the current as being 30 A. Therefore, current detection for a motor by such a driver is imprecise.

### BRIEF DESCRIPTION OF THE DRAWINGS

FIG. 1 is a block diagram of a first exemplary embodiment of a current detecting apparatus.

FIG. 2 is a circuit diagram of the current detecting apparatus of FIG. 1.

FIG. 3 is a block diagram of a second exemplary embodiment of a current detecting apparatus.

FIG. 4 is a block diagram of a third exemplary embodiment of a current detecting apparatus.

### DETAILED DESCRIPTION

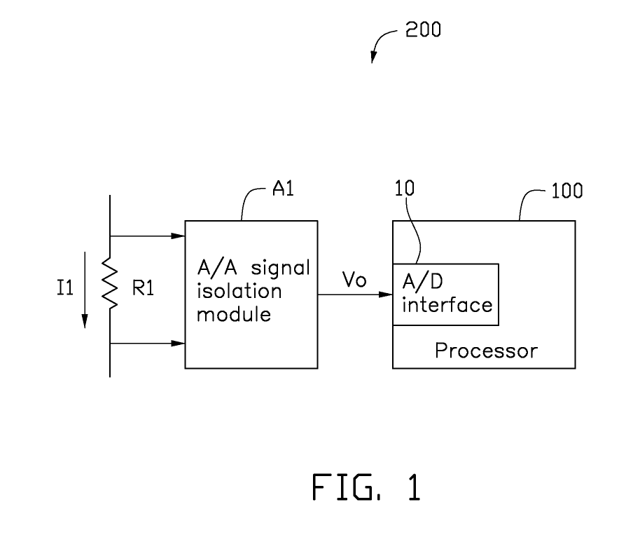

Referring to FIG. 1, a first exemplary embodiment of a current detecting apparatus 200 includes a first resistor R1, an analog-to-analog (A/A) signal isolation module A1, and a processor 100. The processor 100 includes an analog-to-digital (A/D) interface 10. The A/A signal isolation module A1 is connected in parallel to the first resistor R1. The A/D interface 10 of the processor 100 is connected to the A/A signal isolation module A1.

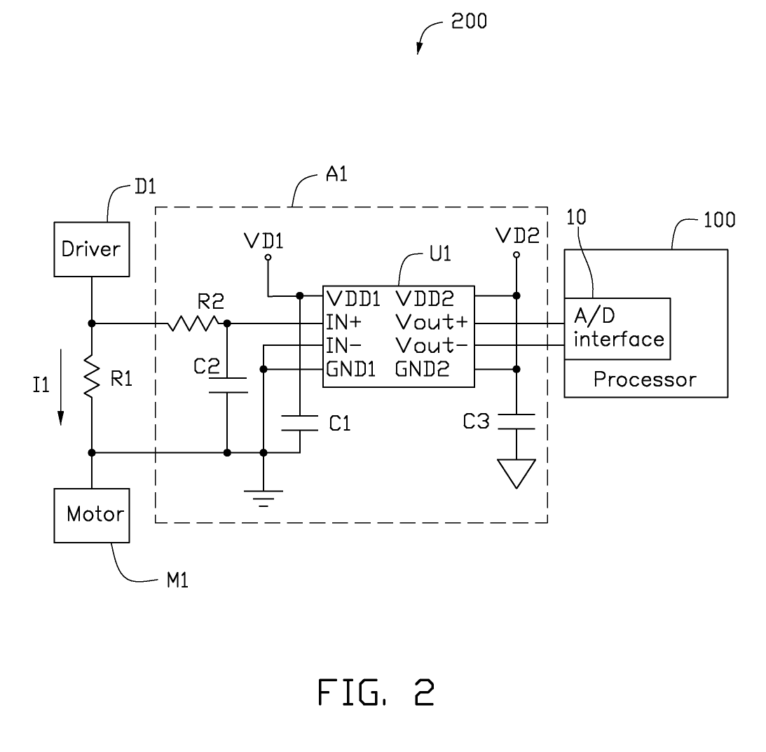

Referring to FIG. 2, in one exemplary embodiment, the A/A signal isolation module A1 includes an A/A signal isolation amplifier U1, a second resistor R2, a first capacitor C1, a second capacitor C2, and a third capacitor C3. The A/A signal isolation amplifier U1 may be an HCPL7840 type integrated circuit (IC) chip. A first end of the first resistor R1 is to be connected to a driver D1, and a second end of the first resistor R1 is to be connected to a motor M1. The driver D1 provides a current I1 for the motor M1 via the first resistor R1 to drive the motor M1. In other embodiments, the A/A signal isolation amplifier U1 can be replaced by an A/A signal isolator.

The A/A signal isolation amplifier U1 includes an input and an output. The input of the A/A signal isolation amplifier U1 includes a positive voltage input pin IN+, a negative voltage input pin IN−, a first power pin VDD1, and a first ground pin GND1. The output of the A/A signal isolation amplifier U1 includes a positive voltage output pin Vout+, a negative voltage output pin Vout−, a second power pin VDD2, and a second ground pin GND2. The first power pin VDD1 is connected to a first power supply VD1, and also connected to the first ground pin GND1 via the first capacitor C1. The positive input voltage pin IN+ is connected to the first end of the first resistor R1 via the second resistor R2, and also connected to the first ground pin GND1 via the second capacitor C2. The negative input voltage pin IN− is connected to the first ground pin GND1, and connected to the second end of the first resistor R1. The first ground pin GND1 is grounded. The second power pin VDD2 is connected to a second power supply VD2, and connected to the second ground pin GND2. The positive output voltage pin Vout+ and the negative output voltage pin Vout− are connected to the A/D interface 10 of the processor 100. The second ground pin GND2 is grounded via the third capacitor C3.

In order to isolate the input and the output of the A/A isolation amplifier U1 from each other, the first power pin VDD1 and the second power pin VDD2 are correspondingly connected to the different power supplies VD1 and VD2 which are both capable of providing about a +5V voltage, and the first ground pin GND1 and the second ground pin GND2 are connected to different grounds. The first capacitor C1, the second capacitor C2, and the third capacitor C3 are configured for wave filtering. The second resistor R2 is configured for current limiting. In one exemplary embodiment, the first capacitor C1, the second capacitor C2, the third capacitor C3, and the second resistor R2 can be omitted to save cost.

The resistance of the first resistor R1 is determined by a maximum input voltage of the positive input voltage pin IN+ of the A/A signal isolation amplifier U1 and a maximum current output by the driver D1. For example, when the maximum input voltage of the positive input voltage pin IN+ of the A/A signal isolation amplifier U1 is about 0.03V, and the maximum current of the driver D1 is about 30 A, thereby the resistance of the first resistor R1 should be approximately 0.03V/30 A=0.001Ω.

An electrical potential difference is formed between the first and second ends of the first resistance R1 when the current I1 passes through the first resistor R1. The electrical potential difference is transmitted to the A/A signal isolation amplifier U1 via the positive input voltage pin IN+ and the negative input voltage pin IN−. The A/A signal isolation amplifier U1 isolates and amplifies the electrical potential difference to output an isolated signal Vo. The isolated signal Vo is transmitted to the A/D interface 10 of the processor 100 for an analog-to-digital signal conversion. The processor 100 processes a digital signal converted by the A/D interface 10 to obtain the value of the current I1 passing through the first resistor R1. In one exemplary embodiment, the processor 100 may include a comparator (not shown), for comparing the digital signal with a determined reference value, so that, for example, when the current I1 is overvalue, an alarm is given.

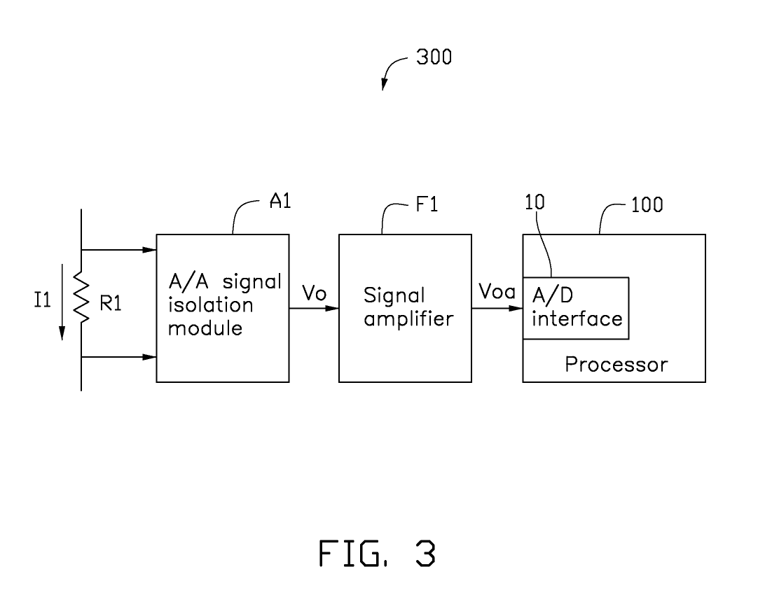

Referring to FIG. 3, since the amplification of the A/A signal isolation amplifier U1 of the current detecting apparatus 200 in FIG. 1 is limited, a signal amplifier F1 is connected between the A/A signal isolation module A1 and the A/D interface c10 in a second exemplary embodiment of a current detecting apparatus 300, for further amplifying the isolated signal Vo. An amplified-isolated signal Voa output from the signal amplifier F1 is transmitted to the A/D interface of the processor 100 for detecting the current I1.

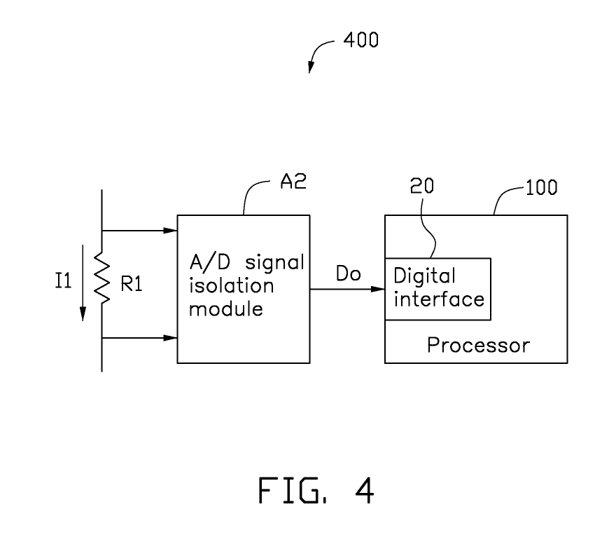

Referring to FIG. 4, in a third exemplary embodiment of a current detecting apparatus 400, an A/D signal isolation module A2 may replace the A/A signal isolation module A1 of the first or second embodiment. The A/D signal isolation module A2 may include an A/D signal isolation amplifier or an A/D isolator. A processor 100 of the current detecting apparatus 400 may include a digital interface 20. When the current I1 passes through the first resistor R1, the electrical potential difference between the first and second ends of the first resistor R1 is transmitted to the A/D signal isolation module A2. The A/D signal isolation module A2 isolates the electrical potential difference, and makes an analog-to-digital conversion of the electrical potential difference. Therefore, an isolation digital signal Do output from the A/D signal isolation module A2 is transmitted to the processor 100 via the digital interface 20. The processor 100 processes the isolated digital signal Do to detect the current I1. In other exemplary embodiments, a signal amplifier may be connected between the A/D signal isolation module A2 and the processor 100 to amplify the isolation digital signal Do.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. A current detecting apparatus for detecting a current provided by a driver for a motor, comprising:
a first resistor, wherein a first end of the first resistor is connected to the driver, and a second end of the first resistor is connected to the motor, wherein the current provided by the driver passes through the first resistor to drive the motor;
a signal isolation module connected between the first end and the second end of the first resistor to receive a voltage signal produced by the current passing through the first resistor and isolate the voltage signal to output an isolated signal; and
a processor connected to the signal isolation module to receive the isolated signal and process the isolated signal to detect the current provided by the driver for the motor.

2. The current detecting apparatus of claim 1, wherein the signal isolation module comprises an analog-to-analog (A/A) signal isolation amplifier.

3. The current detecting apparatus of claim 2, wherein the processor comprises an analog-to-digital (A/D) interface, to receive the isolated signal.

4. The current detecting apparatus of claim 3, wherein the A/A signal isolation amplifier comprises an input and an output; the input of the A/A signal isolation amplifier comprises a positive voltage input pin, a negative voltage input pin, a first power pin, and a first ground pin; the output of the A/A signal isolation amplifier comprises a positive voltage output pin, a negative voltage output pin, a second power pin, and a second ground pin; wherein the positive voltage input pin and the negative voltage input pin are correspondingly connected to the first end and the second end of the first resistor; the positive voltage output pin and the negative voltage output pin are connected to the interface of the processor; the first power pin is connected to a first power supply, the second power pin is connected to a second power supply, and the first ground pin and second ground pin are connected to two different grounds correspondingly.

5. The current detecting apparatus of claim 4, wherein the signal isolation module further comprises a second resistor, a first capacitor, a second capacitor, and a third capacitor; a first end of the second resistor is connected to the first end of the first resistor, and a second end of the second resistor is connected to the positive voltage input pin of the A/A signal isolation amplifier; the first capacitor is connected between the first power pin and the first ground pin of the A/A signal isolation amplifier; the second capacitor is connected between the positive voltage input pin of the A/A signal isolation amplifier and the first ground pin, the first ground pin is grounded via one of the two different grounds; and the third capacitor is connected between the other one of the two different grounds and the second ground pin of the A/A signal isolation amplifier.

6. The current detecting apparatus of claim 1, wherein the signal isolation module comprises an analog-to-digital (A/D) signal isolation amplifier.

7. The current detecting apparatus of claim 6, wherein the processor comprises a digital interface to receive the isolated signal.

8. The current detecting apparatus of claim 1, wherein the resistance of the first resistor is determined by a maximum input voltage of the signal isolation module being divided by a maximum output current of the driver.

9. A current detecting apparatus for detecting a current provided by a driver for a motor, comprising:
a first resistor, wherein a first end of the first resistor is connected to the driver, and a second end of the first resistor is connected to the motor, wherein the current provided by the driver passes through the first resistor to drive the motor;
a signal isolation module connected between the first end and the second end of the first resistor, to receive a voltage signal produced by the current passing through the first resistor and isolate the voltage signal to output an isolated signal;
a signal amplifier connected to the signal isolation module and configured for receiving the isolated signal and amplifying the isolated signal to output an amplified-isolated signal; and
a processor connected to the signal amplifier to receive the amplified-isolated signal and process the amplified-isolated signal to detect the current provided by the driver for the motor.

10. The current detecting apparatus of claim 9, wherein the signal isolation module comprises an analog-to-analog (A/A) signal isolation amplifier.

11. The current detecting apparatus of claim 10, wherein the processor comprises an analog-to-digital (A/D) interface, to receive the amplified-isolated signal.

12. The current detecting apparatus of claim 11, wherein the A/A signal isolation amplifier comprises an input and an output, the input of the A/A signal isolation amplifier comprises a positive voltage input pin, a negative voltage input pin, a first power pin, and a first ground pin; the output of the A/A signal isolation amplifier comprises a positive voltage output pin, a negative voltage output pin, a second power pin, and a second ground pin; wherein the positive voltage input pin and the negative voltage input pin are correspondingly connected to the first end and the second end of the first resistor; the positive voltage output pin and the negative voltage output pin are connected to the interface of the processor via the signal amplifier; the first power pin is connected to a first power supply, the second power pin is connected to a second power supply, and the first ground pin and the second ground pin are connected to two different grounds correspondingly.

13. The current detecting apparatus of claim 12, wherein the signal isolation module further comprises a second resistor, a first capacitor, a second capacitor, and a third capacitor; a first end of the second resistor is connected to the first end of the first resistor, and a second end of the second resistor is connected to the positive voltage input pin of the A/A signal isolation amplifier; the first capacitor is connected between the first power pin and the first ground pin of the A/A signal isolation amplifier; the second capacitor is connected between the positive voltage input pin and the first ground pin of the A/A signal isolation amplifier, the first ground pin is grounded via one of the two different grounds; and the third capacitor is connected between the other one of the two different grounds and the second ground pin of the A/A signal isolation amplifier.

14. The current detecting apparatus of claim 9, wherein the resistance of the first resistor is determined by a maximum input voltage of the signal isolation module being divided by a maximum output current of the driver.
